(19) United States
(12) Patent Application Publication
(10) Pub. No.: US 2026/0010685 A1
(43) Pub. Date: Jan. 8, 2026

(54) MACHINE LEARNING APPARATUS, ELECTRONIC DEVICE, MACHINE LEARNING PROGRAM, AND SIMULATION APPARATUS

(71) Applicant: ROHM CO., LTD., Kyoto-shi (JP)

(72) Inventor: Kenji HAMACHI, Kyoto-shi (JP)

(21) Appl. No.: 19/250,365

(22) Filed: Jun. 26, 2025

(30) Foreign Application Priority Data
Jul. 3, 2024 (JP) 2024-107493

(51) Int. Cl. G06F 30/27; G06F 30/17

(52) U.S. Cl. CPC G06F 30/27; G06F 30/17

(57) ABSTRACT

A machine learning apparatus includes a model holder, a data storage, and a model computing unit. The model holder holds a first machine learning model having undergone supervised learning and a second machine learning model having undergone unsupervised learning. The model computing unit inputs input data to the first machine learning model to generate first output data and inputs the input data also to the second machine learning model to generate accuracy data. The accuracy data is calculated based on a value in at least one of the input layers, the middle layer, and the output layer of the second machine learning model such that the accuracy data changes its tendency in response to the first output data.

### CROSS REFERENCE TO RELATED APPLICATIONS

The present invention claims priority under 35 U.S.C. § 119 to Japanese Application No. 2024-107493 filed in Japan on Jul. 3, 2024, the entire contents of which is incorporated herein by reference.

### BACKGROUND OF THE INVENTION

### 1. Field of the Invention

The present disclosure relates to a machine learning apparatus, an electronic device, a machine learning program, and a simulation apparatus.

Today, AI (artificial intelligence) is increasingly employed in condition-based maintenance of a mechanical system for the maintenance of factory equipment in industrial fields.

### SUMMARY OF THE INVENTION

According to one aspect of the present disclosure, a machine learning apparatus includes a model holder, a data storage, and a computing unit. The model holder is configured to hold a first machine learning model having undergone supervised learning and a second machine learning model having undergone unsupervised learning. The data storage is configured to store input data to be input to the first and second machine learning models. The computing unit is configured to input the input data to the first machine learning model to generate first output data and to input the input data to the second machine learning model to generate accuracy data. The second machine learning model includes an input layer, an output layer, and at least one middle layer between the input and output layers. The accuracy data is calculated based on a value in at least one of the input layers, the middle layer, and the output layer such that the accuracy data changes its tendency in response to the first output data.

According to another aspect of the present disclosure, an electronic device includes the machine learning apparatus configured as described above.

According to another aspect of the present disclosure, a machine learning program makes a computer function as the machine learning apparatus configured as described above.

According to another aspect of the present disclosure, a simulation apparatus calculates, using the machine learning apparatus configured as described above, the accuracy data.

### BRIEF DESCRIPTION OF THE DRAWINGS

FIG. 1 is a diagram showing the configuration of a computer.

FIG. 2 is a block diagram showing the configuration of a machine learning apparatus according to a first embodiment of the present disclosure.

FIG. 3 is a diagram showing the configuration of a prediction model.

FIG. 4 is a diagram showing the configuration of a validation model.

FIG. 5 is a diagram schematically showing how, using input data, a prediction model, and a validation model, first output data is generated and validated.

FIG. 6 is a graph showing one example of input data and first output data.

FIG. 7 is a graph showing first output data and accuracy data.

FIG. 8 is a block diagram showing the configuration of a machine learning apparatus according to a second embodiment of the present disclosure.

FIG. 9 is a diagram schematically showing how, using input data, a prediction model, and a plurality of validation models, first output data is generated and validated.

### DETAILED DESCRIPTION OF PREFERRED EMBODIMENTS

Now, an embodiment of the present disclosure will be described with reference to accompanying drawings.

### Computer 100

First, a description will be given of a computer 100 that functions as a machine learning apparatus 6 according to the present disclosure. After that, the machine learning apparatus 6 according to a first embodiment of the present disclosure will be described in detail.

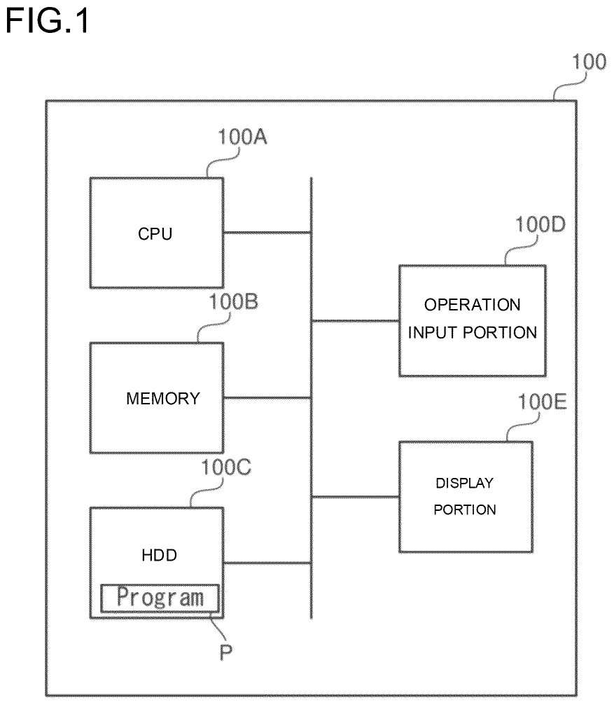

FIG. 1 is a diagram showing the configuration of the computer 100. The computer 100 functions as the machine learning apparatus 6 described later. The computer 100 is, for example, a PC (personal computer).

The computer 100 includes a CPU (central processing unit) 100A, a memory 100B, an auxiliary storage device 100C, an operation input portion 100D, and a display portion 100E.

The CPU 100A includes a control device and a computation device (neither is shown). The control device interprets instructions in a program to control the different parts of the computer 100. The computation device executes arithmetic operations.

The memory 100B is a semiconductor storage device that temporarily stores a program or data. The information stored in the memory 100B is lost when the power to the computer 100 is turned off.

The auxiliary storage device 100C is configured with an HDD (hard disk drive), an SSD (solid-state drive), or the like and stores a program or data. The program stored in the auxiliary storage device 100C is read into the memory 100B. The CPU 100A executes the program read into the memory 100B.

Here, the auxiliary storage device 100C has a simulation program P stored in it. The simulation program P is a program that makes the computer 100 function as the machine learning apparatus 6 described later. The machine learning apparatus 6 will be described in detail later.

The operation input portion 100D is configured with a keyboard, a mouse, and the like and feeds the computer 100 with the input of user operations. The information input through the operation input portion 100D is fed to the memory 100B.

The display portion 100E is configured with, for example, a liquid crystal display and outputs the information acquired from the memory 100B in a form converted into an image.

### Machine Learning Apparatus 6 According to a First Embodiment

Next, a machine learning apparatus 6 according to a first embodiment of the present disclosure will be described. The machine learning apparatus 6 is configured with an MCU (microcontroller unit). The machine learning apparatus 6 is incorporated in a mechanical system (such as a motor device) to control it. The machine learning apparatus 6 can, in addition to controlling the mechanical system, perform machine learning using as input data various kinds of data on the mechanical system.

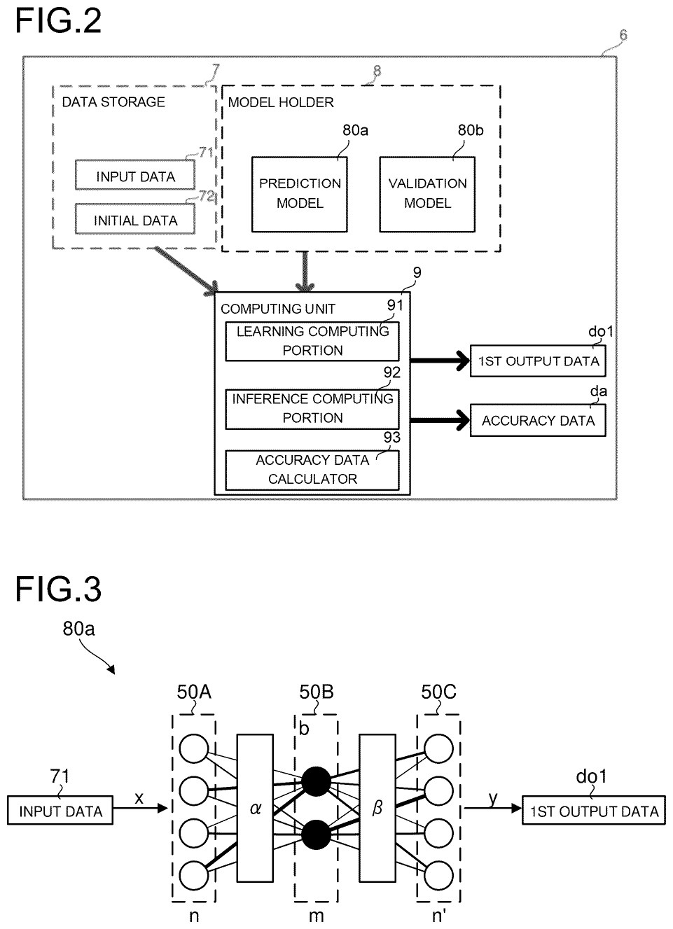

FIG. 2 is a block diagram showing the configuration of the machine learning apparatus 6 according to the first embodiment of the present disclosure. As shown in FIG. 2, the machine learning apparatus 6 includes a data storage 7, a model holder 8, and a computing unit 9.

The data storage 7 stores input data 71 and initial data 72. The input data 71 is, for example, time-series data output from the mechanical system. As necessary, this time-series data can be subjected to preprocessing such as normalization or FFT. In the initial data 72, an initial value determined by the computer 100 as mentioned above is set.

The model holder 8 holds a prediction model 80a and a validation model 80b. The prediction model 80a and the validation model 80b are machine learning models that can learn and infer based on input data. The prediction model 80a and the validation model 80b will be described in detail later.

The computing unit 9 includes a learning computing portion 91 and an inference computing portion 92. The learning computing portion 91 performs supervised learning using the prediction model 80a, the input data 71, and the initial data 72. On the other hand, the learning computing portion 91 performs unsupervised learning using the validation model 80b, the input data 71, and the initial data 72.

The inference computing portion 92 performs inference using the prediction model 80a or validation model 80b, the input data 71, and the initial data 72. Inference can be performed during learning and after completion of learning.

An accuracy data calculator 93 generates accuracy data da using the input data 71 and the validation model 80b.

Next, the prediction model 80a will be described in detail. FIG. 3 is a diagram showing the configuration of the prediction model 80a. As shown in FIG. 3, the prediction model 80a includes a three-layer neural network 50. The prediction model 80a is a trained inference model that has previously learned predetermined learning data.

The three-layer neural network 50 is an AI model that has an input layer 50A, a hidden layer 50B, and an output layer 50C. The hidden layer 50B is referred to also as a middle layer. Generally, with a three-layer neural network 50, for n-dimensional input data of batch size k, that is, x∈Rk×n, the n′-dimensional inference result y∈Rk×n′ is obtained as y=G(x·α+b)β. Here, α∈Rn×m represents the weight with which the input layer 50A and the hidden layer 50B are coupled together; β∈Rm×n′ represents the weight with which the hidden layer 50B and the output layer 50C are coupled together; b∈Rm represents the bias for the hidden layer 50B; and G is the activation function for the hidden layer 50B. Usable as the activation function is, for example, a sigmoid, ReLU, or other functions.

As mentioned above, the prediction model 80a is a trained inference model that has previously learned predetermined learning data with predetermined weights for a and B. In FIG. 3, the weights that are set based on learning are indicated by the thickness of the straight lines that connect together the input layer 50A and the hidden layer 50B and the thickness of the straight lines that connect together the hidden layer 50B and the output layer 50C.

Inputting the input data 71 to the prediction model 80a and performing inference yields first output data do1.

### Study on Accuracy of Output of Machine Learning Model

Generally, supervised learning using a machine learning model is employed in future prediction for time-series data, prediction for a predetermined parameter that is difficult to sense, and the like. However, the accuracy (the degree of reliability) of prediction data resulting from supervised learning is unknown. Inconveniently, this makes it difficult for a user of the machine learning model to judge whether to adopt prediction data generated by a machine learning model or whether to perform learning once again.

To prevent such inconvenience, the machine learning apparatus 6 according to the present disclosure allows the user using it to acquire the accuracy data da. The accuracy data da is data representing the accuracy of an output result (the first output data do1) generated by the prediction model 80a (of which details will be given later). The user can, while referring to the acquired accuracy data da, easily judge whether to adopt an output result and whether to perform learning once again. The machine learning apparatus 6 according to the embodiments of the present disclosure will now be described in more detail.

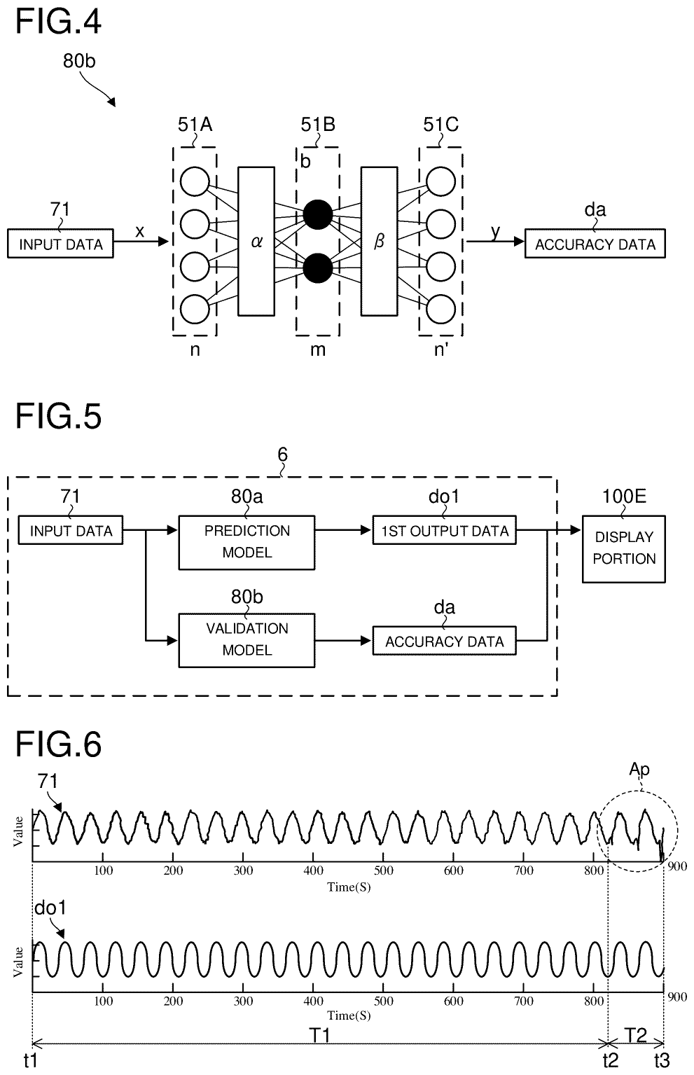

FIG. 4 is a diagram showing the configuration of the validation model 80b. As shown in FIG. 4, the validation model 80b includes a three-layer neural network 51.

The three-layer neural network 51 is an AI model that has an input layer 51A, a hidden layer 51B, and an output layer 51C. The hidden layer 51B is referred to also as a middle layer. Generally, with a three-layer neural network 51, for n-dimensional input data of batch size k, that is, x∈Rk×n, the n′-dimensional inference result y∈Rk×n′ is obtained as y=G(x·γ+b)ι. Here, γ∈Rn×m represents the weight with which the input layer 51A and the hidden layer 51B are coupled together; ι∈Rm×n′ represents the weight with which the hidden layer 51B and the output layer 51C are coupled together; b∈Rm represents the bias for the hidden layer 51B; and G is the activation function for the hidden layer 51B. Usable as the activation function is, for example, a sigmoid, ReLU, or other functions.

The three-layer neural network 50 employs an algorithm that can learn progressively by a desired batch size at a time. When the ith learning data of batch size kᵢ, {xᵢ∈Rkᵢ×n, tᵢ∈Rkᵢ×n′} is obtained, it is necessary to determine βᵢ that minimizes the error given by Expression (1) below.

$$‖ [ \begin{matrix}{H}_{0} \\ ⋮ \\ {H}_{i}\end{matrix} ] {β}_{i} - [ \begin{matrix}{t}_{0} \\ ⋮ \\ {t}_{i}\end{matrix} ] ‖ \qquad ( 1 )$$

Here, the ith hidden-layer matrix is Hᵢ=G(xᵢ·α′b); t is the teaching data for the inference result y.

The optimized weight βᵢ is given by Expression (2) below.

$${P}_{i} = {P}_{i - 1} - {P}_{i - 1} {{{H}_{i}}^{T} ( I + {H}_{i} {P}_{i - 1} {{H}_{i}}^{T} )}^{- 1} {H}_{i} {P}_{i - 1} \qquad ( 2 )$$

$${β}_{i} = {β}_{i - 1} + {P}_{i} {{H}_{i}}^{T} ( {t}_{i} - {H}_{i} {β}_{i - 1} )$$

Here, P₀ and β₀ are given by Expression (3) below.

$${P}_{0} = {( {{H}_{0}}^{T} {H}_{0} )}^{- 1} \qquad ( 3 )$$

$${β}_{0} = {P}_{0} {{H}_{0}}^{T} {t}_{0}$$

The algorithm of learning is as follows:
(1) Initialize the weight a and the bias b with a random number.
(2) Calculate H₀ for x₀, and calculate P₀ and β₀.
(3) Every time the ith learning data of batch size kᵢ is obtained, calculate Pᵢ and βᵢ. Here, β₀ need not be calculated according to the equation for its calculation in Expression (3); a value initialized with a random number can be taken as β₀.

The bottleneck in Expression (2) above in terms of the amount of computation is (I+HᵢPᵢ₋₁Hᵢ^{T})⁻¹; here, the matrix size of (I+HᵢPᵢ₋₁Hᵢ^{T}) is k×k, so if k=1, inverse matrix calculation can be replaced with reciprocal calculation. Accordingly, keeping the batch size k=1 allows easy computation even for a computation device like a microprocessor.

Moreover, in this embodiment, a machine learning model 80 learns using an autoencoder. An autoencoder uses input data as it is as teaching data, and learns in a way that the input data can be reconstructed as an inference result; that is, in terms of what has been described above, it learns assuming that t=x. An autoencoder does not require separately created teaching data and is therefore one kind of unsupervised learning algorithm. Moreover, keeping the number of nodes in a hidden layer smaller than the number of nodes in the input and output layers makes it possible, if the error between the input data and the inference result converges, to regard the hidden-layer matrix as a compressed dimension form of the input data. That is, input data x yields an encoded result H=G(x·γ+b) and H yields a decoded result y=H·ι.

FIG. 5 is a diagram schematically showing how, using the input data 71, the prediction model 80a, and the validation model 80b, the first output data do1 is generated and validated.

As shown in FIG. 5, inputting the input data 71 (corresponding to input data x shown in FIG. 3) to the prediction model 80a and performing inference with the inference computing portion 92 yields first output data do1 as an inference result. Also, inputting the input data 71 (corresponding to input data x in FIG. 4) to the validation model 80b and performing inference with the accuracy data calculator 93 yields accuracy data da as an inference result.

When the computer 100 described above is made to function as the machine learning apparatus 6, the CPU 100A displays on the display portion 100E the first output data do1 and the accuracy data da generated.

As described above, the accuracy data da is data representing the accuracy of the first output data do1 generated by the prediction model 80a. The accuracy data da is comprehensive data that contains various indices, values, graphs, and the like. The accuracy data da will be described in detail later.

The user using the machine learning apparatus 6 can compare the generated first output data do1 with the accuracy data da to analyze or confirm the accuracy (degree of reliability) of the first output data do1. A specific example will be described below.

FIG. 6 is a graph showing one example of the input data 71 and the first output data do1. The input data 71 and the first output data do1 are time-series data with time along the horizontal axis and a given data value along the vertical axis. The input data 71 is predetermined data that the mechanical system incorporating the machine learning apparatus 6 actually outputs. The first output data do1 is data of the inference result obtained by inputting the input data 71 to the prediction model 80a and performing inference.

As shown in FIG. 6, the input data 71 has, in the latter half of its data, a part with an anomaly (indicated by a dotted circle in FIG. 6; in the following description, referred to as “anomalous part Ap”). Here, assume that the mechanical system is in some anomalous condition so that the input data 71 it outputs contains an anomalous value.

Here, the input data 71 starts at time t1. An anomaly in the input data 71 is observed at time t2. The input data 71 ends at time t3. The period from time t1 to time t2 is a normal period T1. The normal period T1 is a period in which the input data 71 exhibits no anomalous value. The period from time t2 to time t3 is an anomalous period T2. The anomalous period T2 is a period in which the input data 71 exhibits an anomalous value.

As described above, the prediction model 80a is a previously trained inference model. The learning data used in the previous learning contains no anomalous value like the anomalous part Ap and basically contains normal values. Thus, inputting the input data 71 containing the anomalous part Ap to the prediction model 80a and performing inference yields, as the inference result, the first output data do1 that contains no anomalous value like the anomalous part Ap.

That is, even if inference is performed using the prediction model 80a, the inference result contains no anomalous value like the anomalous part Ap. Thus, the first output data do1 generated at this time has low accuracy in a part of its latter half (especially in the anomalous period T2). However, as mentioned above, it is difficult for the user to grasp the accuracy of the first output data do1 by simply referring to it. Thus, no judgment can be made on whether to let the prediction model 80a learn once again, whether to reconsider the preprocessing of the input data 71, or the like.

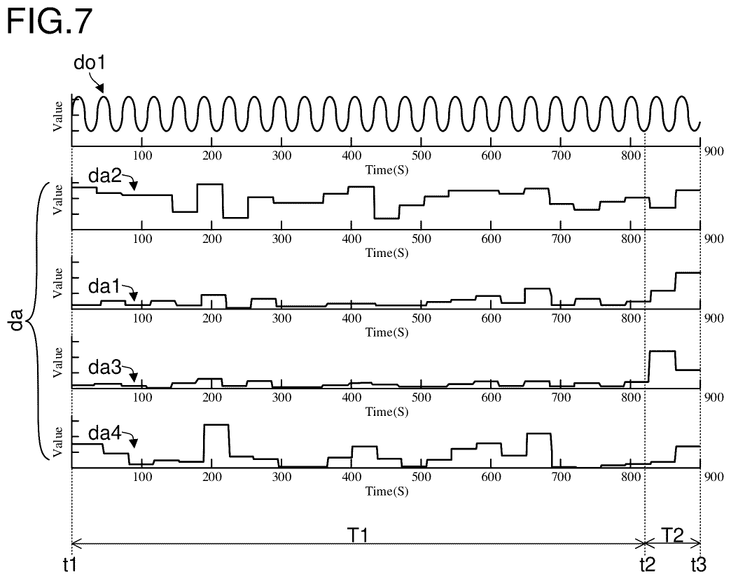

FIG. 7 is a graph showing the first output data do1 and the accuracy data da. Times t1 to t3 in FIG. 7 correspond to times t1 to t3 in FIG. 6. The accuracy data da contains an input-output error da1, a first hidden-layer anomaly level da2, a first hidden-layer error da3, and a second hidden-layer error da4.

The input-output error da1 is calculated based on the input data 71 and second output data do2. The first hidden-layer anomaly level da2, the first hidden-layer error da3, and the second hidden-layer error da4 are calculated based on the hidden-layer 51B. The input-output error da1, the first hidden-layer anomaly level da2, the first hidden-layer error da3, and the second hidden-layer error da4 are each data with a different tendency. How the input-output error da1, the first hidden-layer anomaly level da2, the first hidden-layer error da3, and the second hidden-layer error da4 are each calculated will be described later.

As shown in FIG. 7, assume that the input data 71 has an anomaly in the anomalous period T2. The accuracy data da exhibits a particular tendency in response to the input data 71. The user can, by checking and analyzing this accuracy data da, grasp the degree of discrepancy between the input data 71 and the first output data do1, hence the accuracy of the first output data do1. More specifically, FIG. 7 shows the following.

In the accuracy data da shown in FIG. 7, in the normal period T1, it is difficult to readily find a particular tendency in the first hidden-layer anomaly level da2 and the second hidden-layer error da4. Thus, for the first hidden-layer anomaly level da2 and the second hidden-layer error da4, it is difficult to check for a change in tendency between the normal period T1 and the anomalous period T2.

On the other hand, the input-output error da1 and the first hidden-layer error da3 in the normal period T1 exhibit lower values than the input-output error da1 and the first hidden-layer error da3 in the anomalous period T2. In this way, with the input-output error da1 and the first hidden-layer error da3, it is possible to readily recognize a change in tendency between the normal period T1 and the anomalous period T2.

If accuracy data da as shown in FIG. 7 is generated, the user can, by checking for a change in the tendency of the accuracy data da, estimate that the input data 71 has some anomaly.

Note however that, even if no particular tendency can be found readily, the user can, as he or she gains experience while generating the accuracy data da multiple times or the like, find a particular tendency. In addition, the accuracy data da shown in FIG. 7 is merely an example. Depending on the input data 71, a particular tendency can be observed in the first hidden-layer anomaly level da2 and the second hidden-layer error da4.

### Input-Output Error da1

Next, the input-output error da1, the first hidden-layer anomaly level da2, the first hidden-layer error da3, and the second hidden-layer error da4 will be described. The input-output error da1 represents the error between the second output data do2 and the input data 71. The second output data do2 is data of the inference result obtained by inputting the input data 71 to the validation model 80b and performing inference. The input-output error da1 is calculated based on the input data 71 and the second output data do2 according to a loss function. Specifically, it is calculated as follows.

Each input value contained in the input data 71 will be referred to as input value x. Each output value contained in the second output data do2 (each value in the inference result) will be referred to as output value y. Usable as the loss function for the calculation of the input-output error da1 is, for example, an MAE (mean absolute error), an MSE (mean squared error), or the like. If the loss function is an MAE, the loss function L is given by Expression (4) below.

$$L ( y , x ) = \frac{1}{n ′} \sum \vert y - x \vert \qquad ( 4 )$$

If the loss function is an MSE, the loss function L is given by Expression (5) below.

$$L ( y , x ) = \frac{1}{n ′} \sum {\vert y - x \vert}^{2} \qquad ( 5 )$$

### First Hidden-Layer Anomaly Level da2

The first hidden-layer anomaly level da2 is calculated based on a first hidden-layer vector ha. Specifically, the first hidden-layer anomaly level da2 represents the normalized distance between the first hidden-layer vector ha and the mean vector of the first hidden-layer vector ha. The first hidden-layer vector ha is a vector derived based on the input data 71 and the hidden-layer 51B. Specifically, it is derived as follows.

The first hidden-layer vector ha is a feature vector of the hidden-layer 51B as obtained when the input data 71 is input to the validation model 80b and inference is performed. The first hidden-layer vector ha is given by Expression (6) below.

$${h}_{a} = ( \begin{matrix}{h}_{a 1} \\ {h}_{a 2} \\ ⋮ \\ {h}_{am}\end{matrix} ) \qquad ( 6 )$$

Then the mean vector of the first hidden-layer vector ha is given by Expressions (7) and (8) below.

$$\overline{{h}_{a}} ≡ \frac{1}{m} {\sum }_{i = 1}^{m} {h}_{ai} \qquad ( 7 )$$

$$\overline{{h}_{a}} ≡ ( \begin{matrix}\overline{{h}_{a 1}} \\ \overline{{h}_{a 2}} \\ ⋮ \\ \overline{{h}_{am}}\end{matrix} ) \qquad ( 8 )$$

Accordingly, the first hidden-layer anomaly level da2 is calculated according to Expression (9) below.

$$da {2}^{2} ≡ {( {h}_{a} - \overline{{h}_{a}} )}^{2} {( \frac{1}{m - 1} {h}_{a} {{h}_{a}}^{t} )}^{- 1} ( {h}_{a} - \overline{{h}_{a}} ) \qquad ( 9 )$$

### First Hidden-Layer Error da3

The first hidden-layer error da3 is calculated according to a loss function based on the first hidden-layer vector ha and a second hidden-layer vector hb. The second hidden-layer vector hb is a feature vector of the hidden layer 51B as obtained when the second output data do2 is input to the validation model 80b and inference is performed. The second hidden-layer vector hb is given by Expression (10) below.

$${h}_{b} = ( \begin{matrix}{h}_{b 1} \\ {h}_{b 2} \\ ⋮ \\ {h}_{bm}\end{matrix} ) \qquad ( 10 )$$

The first hidden-layer error da3 is calculated according to a loss function L representing the error between the first hidden-layer vector ha and the second hidden-layer vector hb. If the loss function is an MAE, the loss function L is given by Expression (11) below.

$$L ( {h}_{b} , {h}_{a} ) = \frac{1}{n ′} \sum \vert {h}_{b} - {h}_{a} \vert \qquad ( 11 )$$

If the loss function is an MSE, the loss function L is given by Expression (12) below.

$$L ( {h}_{b} , {h}_{a} ) = \frac{1}{n ′} \sum {\vert {h}_{b} - {h}_{a} \vert}^{2} \qquad ( 12 )$$

### Second Hidden-Layer Error da4

The second hidden-layer error da4 is calculated according to a loss function based on the first hidden-layer anomaly level da2 and a second hidden-layer anomaly level db1. The second hidden-layer anomaly level db1 represents the normalized distance between the second hidden-layer vector hb and the mean vector of the second hidden-layer vector hb.

The mean vector of the second hidden-layer vector hb is given by Expressions (13) and (14) below.

$$\overline{{h}_{b}} ≡ \frac{1}{m} {\sum }_{i = 1}^{m} {h}_{bi} \qquad ( 13 )$$

$$\overline{{h}_{b}} ≡ ( \begin{matrix}\overline{{h}_{b 1}} \\ \overline{{h}_{b 2}} \\ ⋮ \\ \overline{{h}_{bm}}\end{matrix} ) \qquad ( 14 )$$

Accordingly, the second hidden-layer anomaly level db1 is calculated according to Expression (15) below.

$$db {1}^{2} ≡ {( {h}_{b} - \overline{{h}_{b}} )}^{2} {( \frac{1}{m - 1} {h}_{b} {{h}_{b}}^{t} )}^{- 1} ( {h}_{b} - \overline{{h}_{b}} ) \qquad ( 15 )$$

Usable as the loss function for the calculation of the hidden-layer error da4 is, for example, an MAE or the like. If the loss function is an MAE, the hidden-layer error da4 is calculated according to the loss function L given by Expression (16) below.

$$L ( db 1 , da 2 ) = \frac{1}{n ′} \sum \vert db 1 - da 2 \vert \qquad ( 16 )$$

If the loss function is an MSE, the hidden-layer error da4 is calculated according to the loss function L given by Expression (17) below.

$$L ( db 1 , da 2 ) = \frac{1}{n ′} \sum {\vert db 1 - da 2 \vert}^{2} \qquad ( 17 )$$

### Machine Learning Apparatus 6 According to Second Embodiment

Now, a machine learning apparatus 6 according to a second embodiment of the present disclosure will be described. Note that the machine learning apparatus 6 of this embodiment basically shares the same configuration with the machine learning apparatus 6 according to the first embodiment described above. Thus, in the following description, the shared elements are identified by the same reference signs and no overlapping description will be repeated.

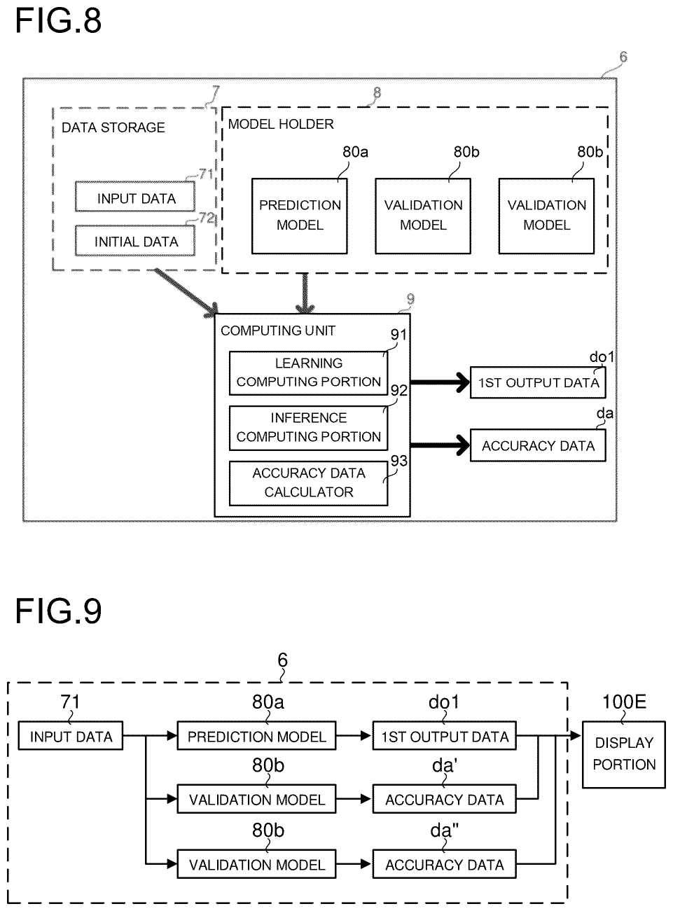

FIG. 8 is a block diagram showing the configuration of the machine learning apparatus 6 according to the second embodiment of the present disclosure. The machine learning apparatus 6 includes a data storage 7, a computing unit 9, and an anomaly detector 10 which are similar to those described above. In addition to these, the machine learning apparatus 6 includes a model holder 20.

The model holder 20 holds a prediction model 80a and a plurality of (here, two) validation models 80b. The two validation models 80b have the same number of nodes in their input layers 50A. The two validation models 80b can have the same or different number of nodes in the hidden layers 50B. The activation functions for the two validation models 80b can be the same or different.

FIG. 9 is a diagram schematically showing how, using the input data 71, the prediction model 80a, and the plurality of validation models 80b, the first output data do1 is generated and validated.

As shown in FIG. 9, one of the validation models 80b is an inference model that has learned normal input data 71 as learning data. The other of the validation models 80b is an inference model that has learned a particular condition (e.g., particular condition including anomalous data) as learning data.

The machine learning apparatus 6 inputs the input data 71 to the prediction model 80a and to each of the plurality of validation models 80b so as to generate the first output data do1 and a plurality of sets of accuracy data da (in the following description, referred to as accuracy data da′ and accuracy data da″).

As described above, one of the validation models 80b is an inference model that has learned a particular condition. Thus, the accuracy data da″ generated by inputting the input data 71 to this validation model 80b exhibits, if the input data 71 has a condition like the particular condition mentioned above, a relatively notable tendency. The user can, by checking and analyzing the accuracy data da′ and the accuracy data da″, estimate the accuracy of the first output data do1.

### Modified Example

The embodiment described above is not meant as any limitation on the present disclosure and thus various modifications can be made without departing from the spirit of the present disclosure. For example, while the accuracy data da is assumed to be comprehensive data that contains various indices, values, graphs, and the like, it can instead contain one predetermined piece of data (e.g., any one piece of the data described above, namely, the input-output error da1, the first hidden-layer anomaly level da2, the first hidden-layer error da3, and the second hidden-layer error da4).

In addition, while the second embodiment described above with reference to FIG. 9 deals as an example with a configuration where the model holder 8 holds the two validation models 80b, the model holder 8 can be one that holds three or more validation models 80b. In this case, too, each of the validation models 80b has the same number of nodes in the input layer 50A; each of the validation models 80b can have the same or different number of nodes in the hidden layer 50B; and the activation function for each of the validation models 80b can be the same or different. In addition, the validation models 80b can but need not have learned predetermined learning data, or they can learn (or re-learn) while inferring.

### Notes

According to one aspect of the present disclosure, a machine learning apparatus (6) includes: a model holder (8) configured to hold a first machine learning model (80a) having undergone supervised learning and a second machine learning model (80b) having undergone unsupervised learning; a data storage (7) configured to store input data (71) to be input to the first and second machine learning models (80a, 80b); and a computing unit (9) configured to input the input data (71) to the first machine learning model (80a) to generate first output data (do1) and to input the input data (71) to the second machine learning model (80b) to generate accuracy data (da). The second machine learning model (80b) includes an input layer (51A), an output layer (51B), and at least one middle layer (51C) between the input and output layers (51A, 51B). The accuracy data (da) is calculated based on a value in at least one of the input layer (51A), the middle layer (51C), and the output layer (51B) such that the accuracy data (da) changes its tendency in response to the first output data (do1). (A first configuration.)

In the machine learning apparatus (6) according to the first configuration, the accuracy data (da) can contain an input-output error (da1) calculated according to a loss function based on values in the input and output layers (51A, 51B). (A second configuration.)

In the machine learning apparatus (6) according to the second configuration, the computing unit (9) can be configured to input the input data (71) to the second machine learning model (80b) and perform inference to generate second output data (do2). The computing unit (9) can calculate the input-output error (da1) according to the loss function based on the input data (71) and the second output data (do2) and can generate a first middle-layer vector based on the value in the middle layer (51C) and a first middle-layer anomaly level (da2) based on the first middle-layer vector. The computing unit (9) is also configured to input the second output data (do2) to the second machine learning model (80b). The computing unit (9) can generate a second middle-layer vector based on the value in the middle layer (51C) and a second middle-layer anomaly level (db1) based on the second middle-layer vector and can calculate a first middle-layer error (da3) according to a loss function based on the first and second middle-layer vectors. The computing unit (9) can calculate a second middle-layer error (da4) according to a loss function based on the first and second middle-layer anomaly levels (da2, db1). The accuracy data (da) contains at least one of the input-output error (da1), the first middle-layer anomaly level (da2), the first middle-layer error (da3), and the second middle-layer anomaly level (db1). (A third configuration.)

According to another aspect of the present disclosure, an electronic device (100A) includes the machine learning apparatus according to any one of the first to third configurations. (A fourth configuration.)

The electronic device (100) according to the fourth configuration can include a display portion (100E) configured to display the first output data (do1) and the accuracy data (da). (A fifth configuration.)

According to another aspect of the present disclosure, a machine learning program (P) makes a computer function as the machine learning apparatus (6) according to any one of the first to third configurations. (A sixth configuration.)

According to another aspect of the present disclosure, a simulation apparatus (100) calculates, using the machine learning apparatus (6) according to any one of the first to third configurations, the first output data (do1) and the accuracy data (da). (A seventh configuration.)

What is claimed is:

1. A machine learning apparatus comprising:
a model holder configured to hold a first machine learning model having undergone supervised learning and a second machine learning model having undergone unsupervised learning;
a data storage configured to store input data to be input to the first and second machine learning models; and
a computing unit configured
to input the input data to the first machine learning model to generate first output data and
to input the input data to the second machine learning model to generate accuracy data,
wherein
the second machine learning model includes:
an input layer;
an output layer; and
at least one middle layer between the input and output layers, and
the accuracy data is calculated based on a value in at least one of the input layer, the middle layer, and the output layer such that the accuracy data changes a tendency thereof in response to the first output data.

2. The machine learning apparatus according to claim 1, wherein
the accuracy data contains an input-output error calculated according to a loss function based on values in the input and output layers.

3. The machine learning apparatus according to claim 2, wherein
the computing unit is configured to input the input data to the second machine learning model and perform inference to generate second output data, and
the computing unit being able to calculate the input-output error according to the loss function based on the input data and the second output data,
the computing unit being able to generate
a first middle-layer vector based on the value in the middle layer and
a first middle-layer anomaly level based on the first middle-layer vector,
the computing unit is configured to input the second output data to the second machine learning model,
the computing unit being able to generate
a second middle-layer vector based on the value in the middle layer and
a second middle-layer anomaly level based on the second middle-layer vector,
the computing unit being able to calculate a first middle-layer error according to a loss function based on the first and second middle-layer vectors, and
the computing unit being able to calculate a second middle-layer error according to a loss function based on the first and second middle-layer anomaly levels, and
the accuracy data contains at least one of the input-output error, the first middle-layer anomaly level, the first middle-layer error, and the second middle-layer anomaly level.

4. An electronic device comprising the machine learning apparatus according to claim 1.

5. The electronic device according to claim 4 comprising a display portion configured to display the first output data and the accuracy data.

6. A machine learning program for making a computer function as the machine learning apparatus according to claim 1.

7. A simulation apparatus configured to calculate, using the machine learning apparatus according to claim 1, the first output data and the accuracy data.
